(19) United States
(12) Patent Application Publication
(10) Pub. No.: US 2007/0002979 A1
(43) Pub. Date: Jan. 4, 2007

(54) Iterative channel estimation using pilot signals

(75) Inventor: Pier Giorgio Verdi, Polesine P. SE (IT)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 10/556,281

(22) PCT Filed: Aug. 10, 2004
(86) PCT No.: PCT/IB04/50617

§ 371 Date: Nov. 9, 2005

(30) Foreign Application Priority Data
May 14, 2003 (EP) 031013311

(51) Int. Cl. H03D 1/04

(52) U.S. Cl. 375/346

(57) ABSTRACT

A set of symbols is transmitted over a communication path affected by fading. The symbols are detected by determining a first channel estimate on the basis of pilot symbols (3) so as to provide first estimated symbols (6), and then determining a second channel estimate on the basis of the first estimated symbols so as to provide second estimated symbols. The number of first estimated symbols (6) involved in the determination of the second channel estimate is substantially equal to the number of pilot symbols (3) involved in the determination of the first channel estimate. This allows the same channel estimation filter circuits to be used in both iterations.

The present invention relates to estimating communications channel properties. More in particular, the present invention relates to detecting symbols received from a communications channel affected by adverse phenomena such as fading.

It is well known that the properties of a communications channel can be influenced by external factors, in particular when the channel involves a wireless section. The transmission path of electromagnetic waves in the air is often influenced by the weather, (moving) objects, interference and other factors. As a result, the properties of the communications channel are not constant but vary in time. Any symbols transmitted over the channel may therefore suffer from unknown changes in their amplitude and phase. In a receiver, the amplitude and/or phase of the symbols is detected. It has been proposed to estimate the channel properties in order to compensate for any signal distortion or degradation which may have occurred due to fluctuations in the transmission path.

U.S. Pat. No. 6,304,624 discloses a detection circuit which estimates a property of a transmission path. A first estimated value of the transmission path property is determined using pilot symbols, whereupon the data symbols are tentatively determined based upon the estimated property of the transmission path. A second estimated value of the transmission path property is then estimated using a pilot symbol and at least one tentatively determined data symbol. The data symbols are finally determined using the second estimated value of the transmission path property.

The detection circuit of the above-mentioned United States Patent comprises at least two propagation path estimating circuits. This is not efficient as substantially the same estimating circuit is duplicated. In addition, it causes the circuit to be relatively complicated. It has also been proposed to use the same estimating circuit in subsequent iterations of the estimation process. However, the estimation processes of the Prior Art first operate on a limited number of pilot symbols in a first iteration, and then on a much larger number of estimated symbols in a second or subsequent iteration. As a result, two different filter circuits are needed for the estimation, one adapted to the limited number of pilot symbols, the other adapted to the larger number of estimated symbols. This still involves a duplication of substantially the same circuits.

It is an object of the present invention to overcome these and other problems of the Prior Art and to provide a method and a device for detecting symbols transmitted over a communications channel which avoid the duplication of circuits while providing a very effective channel estimation.

Accordingly, the present invention provides a method of detecting symbols transmitted over a communications channel, the received symbols comprising pilot symbols having known properties and regular symbols having at least one unknown property, the method comprising the steps of:

obtaining a first channel estimate using the pilot symbols contained in a first temporal window,

producing first estimated symbols on the basis of the first channel estimate,

obtaining a second channel estimate using the first estimated symbols contained in a second temporal window, and

producing second estimated symbols on the basis of the second channel estimate,

wherein the number of first estimated symbols contained in the second temporal window is substantially equal to the number of pilot symbols contained in the first temporal window.

That is, in the second (or any subsequent) step (or iteration) of the method according to the present invention substantially the same number of symbols is processed as in the first step (or iteration). Preferably, the number of symbols in the first and second steps are identical, but embodiments can be envisaged in which any discrepancy in the numbers is compensated by inserting dummy symbols.

As the number of symbols operated on in the first and the second step are equal, or at least substantially equal, the same circuits can be used to process these symbols. More in particular, the same channel estimation filter can be used in the first and the second step.

The method of the present invention may involve more than two steps (iterations), in which case it is preferred that the number of symbols used for estimating the channel properties in each subsequent step is substantially equal to the number of symbols used in the first step.

The temporal windows define sets of symbols used for estimation purposes in terms of their times of arrival at the receiver. It will be understood that these windows merely group the symbols in a sequential order and that instead of the temporal windows referred to above other groupings of symbols could be used.

In a preferred embodiment, the second temporal window is located within the first temporal window. In other words, the estimated symbols used in the second (or subsequent) iteration are derived from the pilot symbols of the corresponding set in the first iteration.

Preferably, the second channel estimate is based upon consecutive estimated symbols. This is, however, not essential and embodiments can be envisaged in which at least some of the estimated symbols used for a further estimation are spaced apart.

The unknown property of the regular symbols may comprise their amplitude. Alternatively, this unknown property may comprise their phase.

The present invention further provides a device for detecting symbols transmitted over a communications channel, the received symbols comprising pilot symbols having known properties and regular symbols having at least one unknown property, the device comprising:

means for obtaining a first channel estimate using the pilot symbols contained in a first temporal window,

means for producing first estimated symbols on the basis of the first channel estimate,

means for obtaining a second channel estimate using the first estimated symbols contained in a second temporal window, and

means for producing second estimated symbols on the basis of the second channel estimate,

wherein the means for obtaining a first channel estimate and the means for obtaining a second channel estimate are the same.

Preferably, the means for producing first estimated symbols and the means for producing second estimated symbols are the same. Advantageously, the means for producing a channel estimate may comprise a filter having a fixed number of filter coefficients. The means for producing estimated symbols may comprise a demodulator.

The present invention is particularly advantageous for detecting turbo codes and may be utilized in various application in the field of communications, for example cellular (mobile) telephony. Accordingly, the present invention additionally provides a communications receiver comprising a device as defined above, and a cellular telephone comprising such a receiver.

The present invention will further be explained below with reference to exemplary embodiments illustrated in the accompanying drawings, in which:

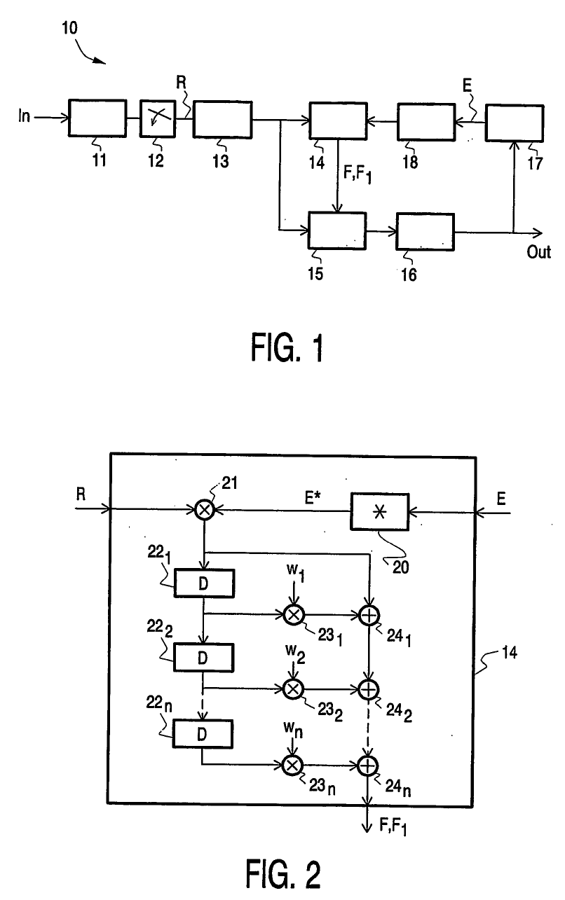

FIG. 1 schematically shows a device for symbol detection which may be used in accordance with the present invention.

FIG. 2 schematically shows part of the detection device of FIG. 1 in more detail.

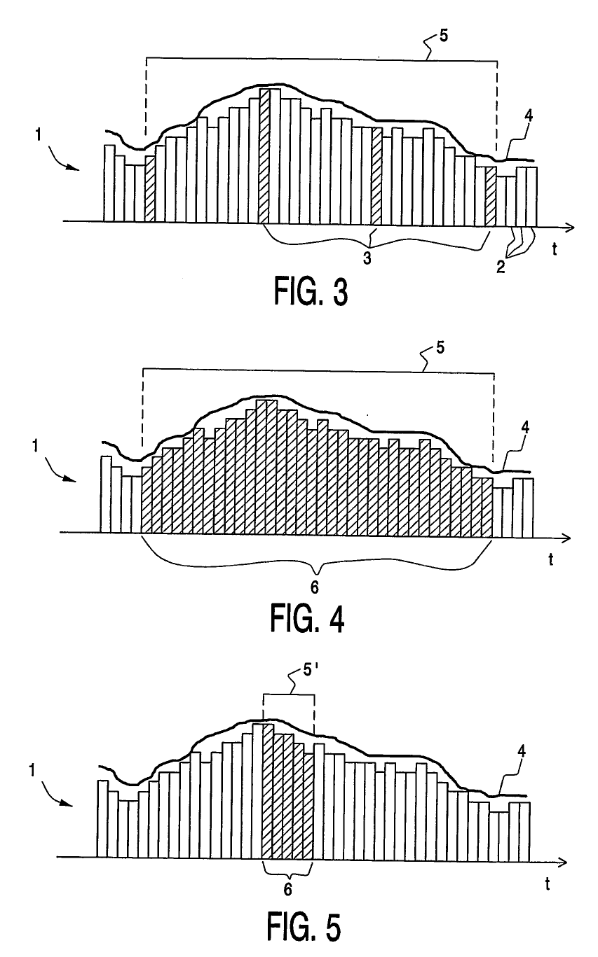

FIG. 3 schematically shows a set of communication symbols used for a first iteration of a channel estimation process.

FIG. 4 schematically shows a set of communication symbols used for a subsequent iteration of a channel estimation process according to the Prior Art.

FIG. 5 schematically shows a set of communication symbols used for a subsequent iteration of a channel estimation process according to the present invention.

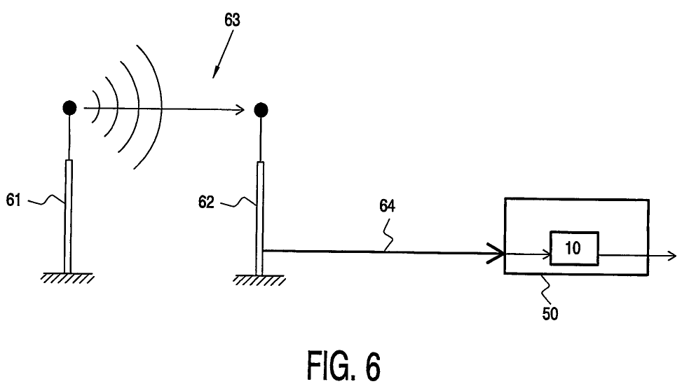

FIG. 6 schematically shows a communications receiver provided with a symbol detection device according to the present invention.

The device 10 shown merely by way of non-limiting example in FIG. 1 comprises a matched filter 11, a sampler 12, a first memory 13, a channel estimation circuit 14, a demodulator 15, a decoder 16, a modulator 17 and a second memory 18. A circuit of this type, and its constituent components, is as such known from the Prior Art. The device 10 operates as follows.

The device 10 receives an input signal from a communications channel. This input signal passes through the matched filter 11 and sampler 12 so as to produce received symbols R (denoted 2 and 3 in FIG. 3) which are stored in the first memory 13. As the communications channel suffers from fading and possibly other undesired phenomena which affect the amplitude and/or phase of the symbols, a channel estimation is carried out so that the imperfections of the channel can be compensated for. To this end, the received symbols are fed to the channel estimation circuit 14 which carries out a channel estimation, as will be explained later in more detail. The channel estimation circuit 14 produces channel coefficients (fading coefficients) F, F′ which are provided to the demodulator 15 which in turn demodulates the symbols taking the estimated channel coefficients into account. The demodulated symbols are then passed on to the decoder 16 which may, for example, be a turbo decoder. The decoder 16 decides on symbol values and outputs the final output symbols. These output symbols are also fed to the modulator 17 which modulates them to produce estimated symbols denoted E in FIG. 1. These estimated symbols are stored in the second memory 18 for comparison with the received symbols R stored in the memory 13.

Any set of received symbols contained in the first memory 13 is operated on at least twice to obtain a better estimation of the channel properties and hence a better compensation of the symbol values and a more accurate determination of those values. In the first iteration, the second memory 18 will initially contain the known values (e.g. amplitudes) of pilot symbols which are used to produce both the channel estimation F and the output symbols from the received samples R. In any subsequent iteration, the second memory 18 will contain the latest estimated (that is, compensated) symbols E which are again combined with the received symbols R to further refine the channel estimation. Although increasing the number of iterations generally produces more accurate results, it has been found that the benefit of large numbers of iterations is relatively small. As a result, it is preferred to carry out only two or three iterations.

The channel estimation may be carried out using a channel estimation circuit 14 as schematically depicted in FIG. 2. The exemplary circuit 14 of FIG. 2 comprises a first multiplication circuit 21 which multiplies each received symbol R with the complex conjugate E* of each estimated symbol E. The complex conjugate symbol E* is determined from each estimated symbol E by a complex conjugate circuit 20 which uses well known mathematical techniques.

The product of the received symbol R and the complex conjugate estimated symbol E* is fed to a filter arrangement comprising a series of delay circuits 22₁, 22₂, . . . , 22ₙ, the output of each delay circuit 22ᵢ (i=1 . . . n) being connected to a respective adding circuit 24ᵢ via a multiplication circuit 23ᵢ. Each multiplication circuit 23ᵢ multiplies the output signal of the associated delay circuit 22ᵢ by a factor wᵢ. The multiplication factors wᵢ are the filter coefficients. In a moving average filter, for example, all filter coefficients wᵢ are equal to 1/n, where n is the number of delay circuits 22. Those skilled in the art will realize that other filter designs are possible in which not all filter coefficients wᵢ have the same value. The channel (fading) coefficients F, F′ are the output of the filter arrangement and of the channel estimation circuit 14.

Returning to FIG. 1 it can be seen that the channel estimation is based upon received signals whose original properties (amplitude and phase) are typically not known to the circuit 10. It has therefore been proposed to transmit pilot symbols having known properties and to base the channel estimation exclusively on these pilot symbols. This has been illustrated in FIG. 3, where a symbol set 1 is shown to comprise regular symbols 2 and pilot symbols 3. As indicated above, the regular symbols 2 typically have unknown properties (amplitude and/or phase), while the properties of the pilot symbols 3 are known to the circuit 10 (FIG. 1). As can be seen, the received symbols 2 and 3 have an amplitude which is affected by the channel fading indicated at 4. The circuit 14 of FIG. 2 serves to estimate the extent of the fading so that the circuit 15 may compensate for it, for example simply by multiplying the received symbols by the fading coefficients.

In FIG. 3 a temporal window 5 is applied, the dimensions of which are typically dictated by ia. the rate of change of the channel fading. In the example shown, four pilot symbols 3 are within the window 5. In the first iteration, only these four pilot symbols will be used (it will be understood that the number of four pilot symbols is provided by way of example only and that in practical embodiments smaller or larger numbers of pilot symbols within one window may be used). The corresponding filter of the channel estimation circuit 14 requires four stages, that is, four delay circuits 22 and associated multiplication and addition circuits, and consequently the filter requires four filter coefficients wᵢ. At the end of the first iteration, estimated symbols (E) are stored in the second memory 18.

According to the Prior Art and as shown in FIG. 4, the second iteration (and any optional subsequent iteration) involves using all estimated symbols 6 within the temporal window 5 to produced an improved set of estimated symbols. This requires a new or amended filter in the channel estimation circuit 14 as the number of symbols to be taken into account is not four, as during the first iteration, but thirty-four (in the particular example illustrated here). Although this typically results in a significant improvement in the channel estimation, it is inconvenient in that it requires two filters to be used instead of one.

According to the present invention, this problem is solved by using, instead of the temporal window 5 of FIGS. 3 and 4, a modified temporal window 5′ as shown in FIG. 5. This modified temporal window 5′ is chosen in such a way that the number of estimated symbols 6 involved in the second iteration equals the number of pilot symbols 3 used in the first iteration. In other words, in each iteration the number of symbols involved is the same. As a result, the same filter can be used in each iteration. It will be clear that this is an important advantage over the Prior Art. Furthermore it has been found that the method of the present invention provides very satisfactory results, also when the rate of change of the channel fading is relatively high.

The receiver 50 shown schematically in FIG. 6 is connected to a communications channel comprising a transmitter antenna 61, a receiver antenna 62, a transmission path 63 between the antennas 61 and 62, and a transmission line 64 connecting the receiver antenna 62 and the receiver 50. As shown in FIG. 6, the receiver 50 contains a detection device 10 according to the present invention. The receiver 50 may contain further components which are not shown for the sake of clarity.

The present invention is based upon the insight that using an increasing number of symbols in subsequent iterations is impractical as it requires a different filter to be used in every iteration The present invention is further based upon the insight that using a relatively small number of symbols in the second (and any subsequent) iterations can still provide excellent results.

It is noted that any terms used in this document should not be construed so as limit the scope of the present invention. In particular, the words “comprise(s)” and “comprising” are not meant to exclude any elements not specifically stated. Single (circuit) elements may be substituted with multiple (circuit) elements or with their equivalents. Any reference signs in the claims should of course not be construed so as to limit the scope of the claims.

It will be understood by those skilled in the art that the present invention is not limited to the embodiments illustrated above and that many modifications and additions may be made without departing from the scope of the invention as defined in the appending claims.

1. A method of detecting symbols transmitted over a communications channel, the received symbols (R) comprising pilot symbols (3) having known properties and regular symbols (2) having at least one unknown property, the method comprising the steps of: obtaining a first channel estimate (F) using the pilot symbols contained in a first temporal window (5),
producing first estimated symbols (R, 6) on the basis of the first channel estimate,
obtaining a second channel estimate (F′) using the first estimated symbols (6) contained in a second temporal window (5′), and
producing second estimated symbols on the basis of the second channel estimate (F′),
wherein the number of first estimated symbols (6) contained in the second temporal window (5′) is substantially equal to the number of pilot symbols (3) contained in the first temporal window (5).

2. The method according to claim 1, wherein the second temporal window (5′) is located within the first temporal window (5).

3. The method according to claim 1 wherein the second channel estimate (F′) is based upon consecutive first estimated symbols (6).

4. The method according to claim 1, wherein the unknown property comprises the amplitude of the symbols.

5. A device (10) for detecting symbols transmitted over a communications channel, the received symbols (R) comprising pilot symbols (3) having known properties and regular symbols (2) having at least one unknown property, the device comprising:
means for obtaining a first channel estimate (F) using the pilot symbols contained in a first temporal window (5),
means for producing first estimated symbols (R, 6) on the basis of the first channel estimate,
means for obtaining a second channel estimate (F′) using the first estimated symbols (6) contained in a second temporal window (5′), and
means for producing second estimated symbols on the basis of the second channel estimate (F′),
wherein the means (14) for obtaining a first channel estimate (F) and the
means (14) for obtaining a second channel estimate (F′) are the same.

6. The device according to claim 5, wherein the means for producing first estimated symbols and the means for producing second estimated symbols are the same.

7. The device according to claim 5, wherein the means for producing a channel estimate comprises a filter having a fixed number of filter coefficients.

8. The device according to claim 5, wherein the means for producing estimated symbols comprise a demodulator.

9. The device according to claim 5, further comprising a first memory (13) for storing received symbols (R) and/or a second memory (18) for storing estimated symbols (E).

10. The device according to claim 5, further comprising a decoder (16), said decoder preferably being a turbo decoder.

11. A communications receiver (50), comprising a device (10) according to claim 5.

12. A cellular telephone set comprising a communications receiver (50) according to claim 11.
